(19) United States
(12) Patent Application Publication
(10) Pub. No.: US 2023/0260851 A1
(43) Pub. Date: Aug. 17, 2023

(54) 3D SINGLE CRYSTAL SILICON NANO SHEETS INTEGRATED WITH 2D MATERIAL CHANNEL AND S/D DIODE ENHANCEMENT

(71) Applicant: Tokyo Electron Limited, Tokyo (JP)

(72) Inventors: H. Jim Fulford, Albany, NY (US); Mark I. Gardner, Albany, NY (US); Partha Mukhopadhyay, Albany, NY (US)

(73) Assignee: Tokyo Electron Limited, Tokyo (JP)

(21) Appl. No.: 17/672,541

(22) Filed: Feb. 15, 2022

(51) Int. Cl. H01L 21/8258; H01L 27/092; H01L 29/06; H01L 29/423; H01L 29/76; H01L 29/786; H01L 21/02; H01L 29/66

(52) U.S. Cl. CPC H01L 21/8258; H01L 27/0922; H01L 29/0665; H01L 29/42392; H01L 29/7606; H01L 29/78618; H01L 29/78696; H01L 21/0259; H01L 21/02532; H01L 21/02579; H01L 21/02576; H01L 21/02645; H01L 29/66742; H01L 29/66969

(57) ABSTRACT

Methods for the manufacture of semiconductor devices constructed with three-dimensional (3D) single crystal silicon nano sheets integrated with two-dimensional (2D) materials are disclosed. A device may include a semiconductor material and having a first end and a second end doped with a first polarity; a seed material wrapping around the semiconductor material; a two-dimensional (2D) material around the seed material; an active gate around the 2D material; and a source/drain structure in contact with the first end and the second end of the semiconductor material and in contact with the 2D material, wherein the source/drain structure is doped with a second polarity opposite to the first polarity.

### TECHNICAL FIELD

The present invention relates generally to the field of manufacturing semiconductor devices.

### BACKGROUND

In the manufacture of a semiconductor devices (especially on the microscopic scale), various fabrication processes are executed, such as film-forming depositions, etch mask creation, patterning, material etching and removal, and doping treatments. These processes are performed repeatedly to form desired semiconductor device elements on a substrate. Conventional microfabrication techniques only manufacture transistors in one plane, while wiring or metallization is formed above the active device plane. Such devices are accordingly characterized as two-dimensional (2D) circuits, manufactured using 2D fabrication techniques. Although scaling efforts have greatly increased the number of transistors per unit area in 2D circuits, these 2D fabrication techniques are approaching physical atomic limitations with single digit nanometer semiconductor device fabrication nodes. Semiconductor device fabricators have expressed a desire for semiconductor circuits having transistors with increased complexity and dimensionality.

### SUMMARY

A variety of semiconductor devices that integrate 2D materials with three-dimensional (3D) single crystal nano sheets are proposed, which aim to overcome scaling limitations experienced in planar devices by increasing transistor density in volume rather than area. The devices and methods may utilize nano sheet masks to form openings in stacks of layers, allowing for precise deposition or formation of 2D materials and other semiconductor materials. Such 2D materials have the potential for very high mobility and therefore enable sub-nanometer channel thickness regions. Such techniques can enable future nanoscale transistors, which may be implemented in a variety of logical circuits, including central processing units (CPUs), graphics processing units (GPUs), and field-programmable gate arrays (FPGAs).

One embodiment is directed to a method. The method may comprise forming a dielectric material on a first side and a second side of a stack of layers, the stack of layers including a layer of a semiconductor material; removing one more layers of the stack of layers to expose the semiconductor material, wherein a first end of the semiconductor material contacts the first side of the dielectric layer and a second end of the semiconductor material contacts the second side of the dielectric layer; selectively forming a seed material around the semiconductor material; selectively forming a two-dimensional (2D) material around the seed material; forming an active gate round the 2D material; doping the first end and the second end of the semiconductor material; and growing source/drain structures at the first end and the second end of the semiconductor material and in contact with two ends of the 2D material, respectively, wherein the first end and the second end of the semiconductor material are doped with a first polarity and the source/drain structures are doped with a second polarity opposite to the first polarity.

The semiconductor material may be silicon, and wherein doping the first end and the second end of the semiconductor material may comprise performing a p-type doping process on the silicon. The semiconductor material is silicon, and wherein doping the first end and the second end of the semiconductor material may comprise performing an n-type doping process on the silicon.

The stack of layers may include one or more layers of a sacrificial material on the semiconductor material. Forming the seed material and the 2D material may comprise replacing the one or more layers of the sacrificial material with the seed material and the 2D material.

Forming the active gate may comprise forming a high-k dielectric material on the 2D material, and forming a gate metal on the high-k dielectric material. Growing the source/drain structures may be performed via a one or more openings in the stack of layers.

Another embodiment is directed to a device. The device may comprise a semiconductor material and having a first end and a second end doped with a first polarity; a seed material around the semiconductor material; a two-dimensional (2D) material around the seed material; an active gate around the 2D material; and a source/drain structure in contact with the first end and the second end of the semiconductor material and in contact with the 2D material, wherein the source/drain structure is doped with a second polarity opposite to the first polarity.

A remaining portion of the bridge may be doped with the second polarity such that a bipolar junction transistor (BJT) is formed by the source/drain structure, the first end of the semiconductor material, and a portion of the semiconductor material. A diode may be formed by the source/drain structure and the first end of the semiconductor material.

The active gate may further comprise a high-k dielectric around the 2D material, and the source/drain structure is electrically isolated from a gate metal of the active gate with the high-k dielectric. The semiconductor material may include silicon. The first polarity may be n-type, and the second polarity may be p-type.

Yet another embodiment is directed to a transistor structure. The transistor structure may include a two-dimensional (2D) channel material partially around a semiconductor material that is at least partially doped with a first polarity; a high-k dielectric partially around the 2D channel material; a gate metal partially around the high k-dielectric; a source metal doped with a second polarity that is opposite to the first polarity, the source metal in contact with the 2D material; and a drain metal doped with the second polarity and in contact with the 2D material.

The method may include a seed material around the semiconductor material, wherein the 2D channel material is in contact with to the seed material. The source metal and the drain metal may be in contact with a portion of the semiconductor material that is doped with the first polarity. The source metal and the drain metal may be in contact with the 2D material and the high-k dielectric material. A central portion of the semiconductor material may be doped with the second polarity, and end portions of the semiconductor material may be doped with the first polarity. The semiconductor material may include silicon.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification. Aspects can be combined and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIGS. 1-24 show various views of a first process flow to manufacture semiconductor devices with 3D single crystal silicon nano sheets integrated with 2D materials, according to an embodiment;

FIGS. 25-31 show various views of a second process flow to manufacture semiconductor devices with 3D single crystal silicon nano sheets integrated with 2D materials, according to an embodiment;

FIGS. 32-36 show various views of a third process flow to manufacture semiconductor devices with 3D single crystal silicon nano sheets integrated with 2D materials, according to an embodiment; and

FIG. 37 shows a flow diagram of an example method for fabricating devices using the process flows described in connection with FIGS. 1-36, according to an embodiment.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

The embodiments described herein provide techniques to manufacture semiconductor devices using 3D single crystal silicon nano sheets integrated with 2D materials. The present techniques include provide a nano sheet design for fabricating transistors with 2D material as a channel of the transistor, and an epitaxial doped region grown as a source or drain contact. One implementation includes a plasma doped silicon nano sheet, which provides low leakage over conventional techniques. Such techniques can form a diode structure at both ends of the source/drain contacts and the silicon nano sheet. With inverse biasing, the silicon nano sheet will appear as highly resistive. Therefore, a 2D material formed on the silicon nano sheet (e.g., using a seed material) may act as the only path (e.g., a channel) between the source and drain. The 2D material can selectively deposited on a seed material, which may be deposited as a nano sheet layer on the silicon nano sheet.

In another implementation, the silicon nano sheet can be grown as an epitaxially doped material. In another implementation, both the silicon nano sheet can be grown as epitaxially doped material and plasma doping can be applied to achieve low leakage. This can form a diode structure at both ends of the source/drain contacts and the doped silicon nano sheet. The present techniques can be used to create any type of semiconductive device, including NMOS devices, PMOS devices, and CFET devices. The techniques described herein may be implemented utilizing pre-aligned masks to improve etching various layers or openings during device fabrication.

Reference will now be made to the figures, which for the convenience of visualizing the fabrication techniques described herein, illustrate a variety of materials undergoing a process flow in various views. Unless expressly indicated otherwise, each Figure represents one (or a set) of fabrication steps in a process flow for manufacturing the devices described herein. In the various views of the Figures, connections between conductive layers or materials may or may not be shown. However, it should be understood that connections between various layers, masks, or materials may be implemented in any configuration to create electric or electronic circuits. When such connections are shown, it should be understood that such connections are merely illustrative and are intended to show a capability for providing such connections, and should not be considered limiting to the scope of the claims.

Likewise, although the Figures and aspects of the disclosure may show or describe devices herein as having a particular shape, it should be understood that such shapes are merely illustrative and should not be considered limiting to the scope of the techniques described herein. For example, the techniques described herein may be implemented in any shape or geometry for any material or layer to achieve desired results. In addition, examples in which two transistors or devices are shown stacked on top of one another are shown for illustrative purposes only, and for the purposes of simplicity. Indeed, the techniques described herein may provide for one to any number of stacked devices. Further, although the devices fabricated using these techniques are shown as transistors, it should be understood that any type of electric electronic device may be manufactured using such techniques, including but not limited to transistors, variable resistors, resistors, and capacitors.

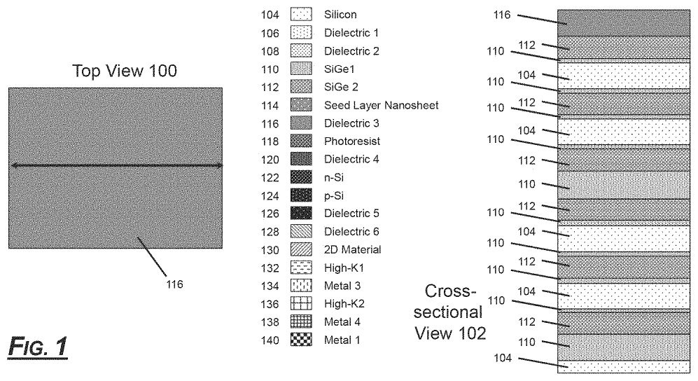

FIGS. 1-24 show various views of a first process flow to manufacture semiconductor devices with 3D single crystal silicon nano sheets integrated with 2D materials. Each of the FIGS. 1-24 generally refer to one or more process steps in a process flow, each of which are described in detail in connection with a respective Figure. For the purposes of simplicity and ease of visualization, some reference numbers may be omitted from some Figures.

Referring to FIG. 1, illustrated is a top view 100 and a cross-sectional view 102 of a base structure (shown here as a stack of layers, however, any base structure can be used in connection with the techniques described herein). The techniques described herein may be used to form material on a base layer 104 which in these example process flows is shown as silicon (“Silicon” in the legend, and the material making up the base layer may be referred to as “silicon 104”). The layers formed on the base layer 104 can be 3D nano sheet layers, which may be formed using any suitable material deposition technique, including atomic layer deposition (ALD), chemical vapor deposition (CVD), physical vapor deposition (PVD), plasma-enhanced CVD (PECVD), or epitaxial growth or deposition techniques. As used herein, the terms “first,” “second,” “third,” and “fourth” with respect to particular layers refer to the order of the layers relative to the base layer 104. For example, a “first” layer of a particular type refers to the specified type of layer which is closest to the base layer 104. Likewise, a “second” layer of a particular type refers to the specified type of layer which is second closest to the base layer 104, and so on.

Alternating layers of sacrificial material may be grown on top of the base layer 104. As shown, a layer of a first sacrificial material 110 (shown as “SiGe1” in the legend) is formed on the base layer 104, and a second sacrificial material 112 (shown as “SiGe 2” in the legend) is formed on the layer of the first sacrificial material. The first sacrificial material 110 may be SiGe, and the second sacrificial material may be SiGe2. A second layer of the first sacrificial material 110 can then be formed on the second sacrificial material 112, and then a layer of silicon 104 can be formed on the second layer of the first sacrificial material 110. A layer of the first sacrificial material is then formed on the silicon 104. As shown, alternating layers of the first sacrificial material 110, the second sacrificial material 112, and the silicon 104 can be formed in the stack of layers to define a number of vertically stacked transistor structures. Each of the first sacrificial material 110, the second sacrificial material 112, and the silicon 104 can be formed using epitaxial growth or formation techniques, using the prior layer as a seed layer. The silicon 104 can be formed as a single crystal 3D nano sheet structure (e.g., having a thickness in the nanometer range, etc.). After forming all of the layers of the first sacrificial material 110, the second sacrificial material 112, and the silicon 104, a layer of a first dielectric material 116 (shown as “Dielectric 3” in the legend) can be formed at the top of the device. A chemical-mechanical polish (CMP) process may be performed prior to further process steps.

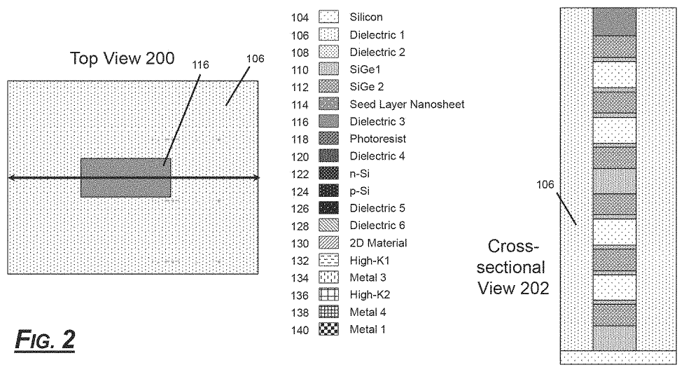

Referring to FIG. 2, illustrated is a top view 200 and a cross-sectional view 202 of the next stage in the process flow. At this stage in the process flow, the stack of layers formed on the base layer 104 can be etched to a desired width and length, as shown in the top view 200. Although the stack of layers has been etched in a rectangle shape, it should be understood that the stack of layers can be formed in any desired geometry. The width or length can be chosen based on desired electrical characteristics of the device. Any suitable etching or material removal technique can be used, including but not limited to dry etching, wet etching, or plasma etching techniques, among others. A nano sheet mask may be used to pattern the stack of layers prior to etching. The etching process may have an etch stop at the base layer 104. After etching the stack of layers, a second dielectric material 106 (shown as “Dielectric 1” in the legend) can be deposited to surround the stack of layers using any suitable material deposition technique, as shown in the top view 200 and the cross-sectional view 202.

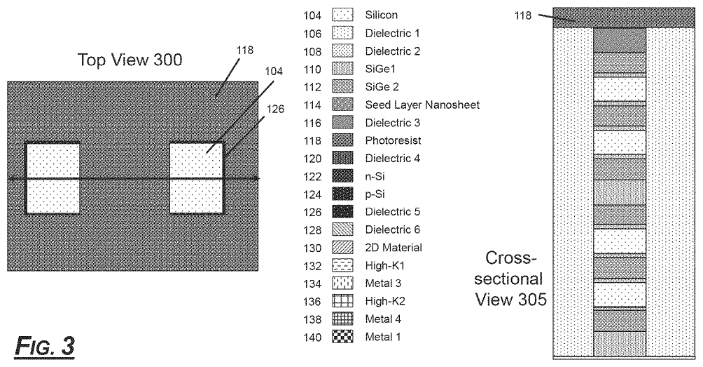

Referring to FIG. 3, illustrated is a top view 300 and a cross-sectional view 302 of the next stage in the process flow. At this stage in the process flow, one or more openings (sometimes referred to herein as “source/drain openings”) can be formed through the second dielectric material 106, adjacent to one or more corresponding sides of the now-etched base structure. The source/drain openings can define the regions that will be occupied by contacts that form the source/drain of one or more transistor structures formed using the present techniques. The source/drain openings can be defined using a nano sheet mask 118 (shown in the legend as “Photoresist”) over the top of the second dielectric material 106. Any suitable etching or material removal technique can be used, including but not limited to dry etching, wet etching, or plasma etching techniques, among others. Although two openings are shown here, it should be understood that any number of openings can be formed through the second dielectric material 106 for use in further process steps.

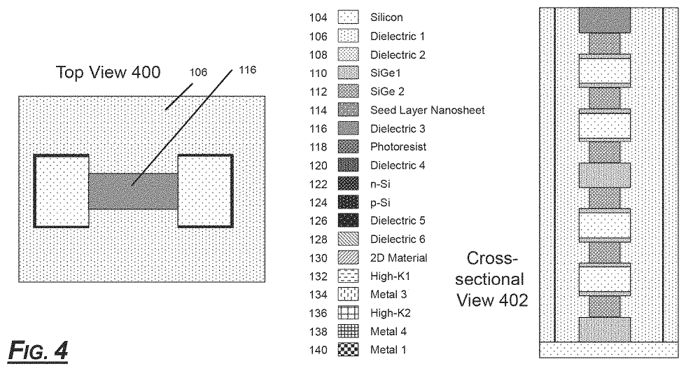

Referring to FIG. 4, illustrated is a top view 400 and a cross-sectional view 402 of the next stage in the process flow. At this stage in the process flow, the second sacrificial material 112 can be etched partially via the openings formed in the previous stage. The etching process used may be a selective etching process, which leaves the other layers and other materials shown in FIG. 4 intact while partially etching the second sacrificial material 112. However, in some implementations, a protective layer may be selectively deposited over the other layers in the stack of layers to protect those layers from the etching process used to recess the second sacrificial material 112. The protective layer can then be removed prior to performing further process steps. Etching the second dielectric material can create one or more recessed air gaps in the regions previously occupied by the second sacrificial material 112. Etching the second sacrificial material 112 in this manner can isolate metal contacts for the source/drain from the gate metal in later process steps, as will be described in greater detail herein.

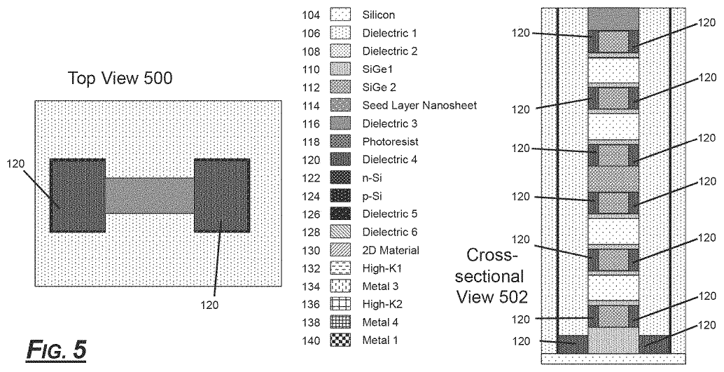

Referring to FIG. 5, illustrated is a top view 500 and a cross-sectional view 502 of the next stage in the process flow. At this stage in the process flow, the openings etched through the second dielectric material 106, and the recessed air gaps formed by etching the second sacrificial material 112, can be deposit-filled with a third dielectric material 120 (shown as “Dielectric 4” in the legend). In some implementations, a CMP process may be performed after depositing the third dielectric material 120. Then, the third dielectric material 120 can be directionally etched until it is just below (e.g., exposing in the source/drain openings) the top of the first layer of the first sacrificial material 110, as shown in the cross-sectional view 502. Etching the third dielectric material 120 re-exposes the sides of the etched stack of layers (including the silicon 104) in the source/drain openings, while isolating the source/drain openings from the base layer 104. The third dielectric material 120 is directionally etched such that the recessed air gaps formed when etching the second sacrificial material 112 are now filled with the third dielectric material 120. In some implementations, the third dielectric material 120 can be directionally etched such that the base layer 104 is exposed in the source/drain openings.

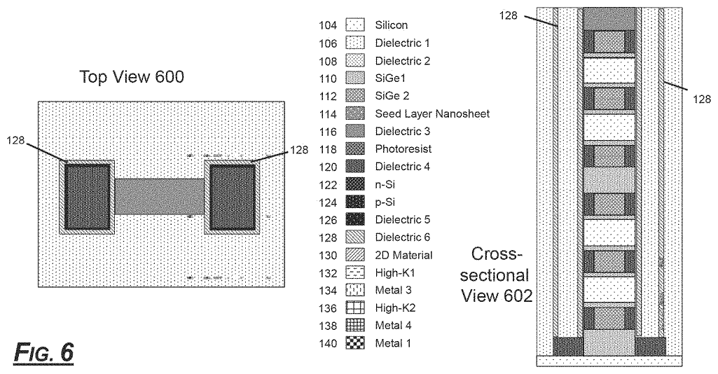

Referring to FIG. 6, illustrated is a top view 600 and a cross-sectional view 602 of the next stage in the process flow. At this stage in the process flow, a layer of a fourth dielectric material 128 (shown in the legend as “Dielectric 6”) can be deposited in the source/drain openings to protect the layers in the stack of layers from further process steps. To do so, a layer of the fourth dielectric material 128 can be deposited in the source/drain openings, using any suitable material deposition technique (e.g., ALD, CVD, PVD, PECVD, etc.). The fourth dielectric layer 128 can be a substantially thin layer of material, such that it does not entirely fill the source/drain openings, as shown in the cross-sectional view 602. The fourth dielectric material 128 can then be directionally etched to expose the third dielectric material 120 in the source/drain openings, as shown in the top views 600.

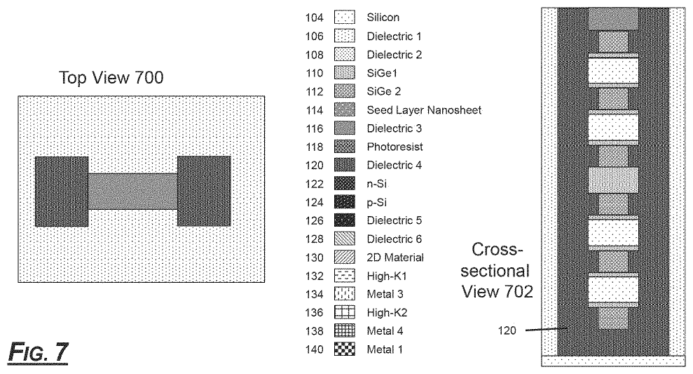

Referring to FIG. 7, illustrated is a top view 700 and a cross-sectional view 702 of the next stage in the process flow. At this stage in the process flow, both the third dielectric material 120 and the first layer of the first sacrificial material 110 can be removed via selective etching processes. Any suitable material removal technique can be used to remove the third dielectric material 120 and the first layer of the first sacrificial material 110, as long as the removal technique is de-selective to the fourth dielectric material 128 (e.g., such that the fourth dielectric material 128 protects the other layers in the stack of layers from removal). The layer of the fourth dielectric material 128 can then be selectively removed using a suitable etching or removal technique. Then, the third dielectric material 120 can be formed in the source/drain openings using any suitable material deposition technique, such that the third dielectric material 120 fills both the source/drain openings and the openings formed by removing the first layer of the first sacrificial material 110, as shown in the cross-sectional view 702. A CMP process may then be performed.

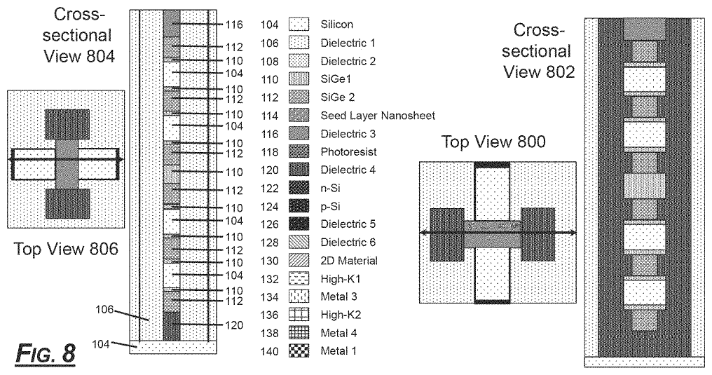

Referring to FIG. 8, illustrated are top views 800, 806 and cross-sectional views 802, 804 of the next stage in the process flow. At this stage in the process flow, one or more gate openings can be formed through the second dielectric material 106, adjacent to one or more corresponding sides of the stack of layers, different from the sides adjacent to the source/drain openings. The gate openings can define the regions that will be occupied by active gate materials, including the gate metals, gate dielectric materials, and other materials, for transistor structures formed using the present techniques. The gate openings can be defined using a nano sheet mask over the top of the first dielectric material 116. Any suitable etching or material removal technique can be used, including but not limited to dry etching, wet etching, or plasma etching techniques, among others, to etch the second dielectric material 106. The gate openings may have an etch stop at the base layer 104, as shown in the top view 806.

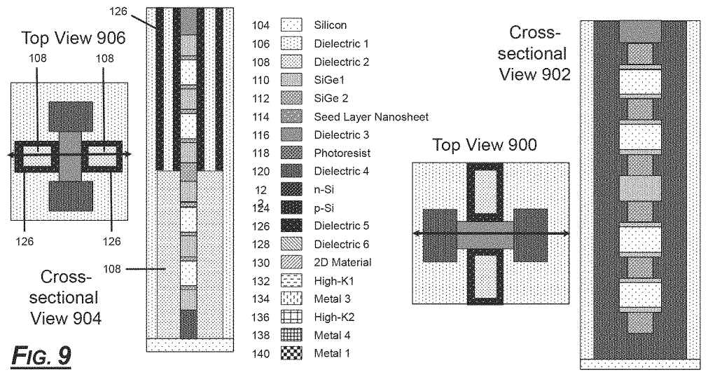

Referring to FIG. 9, illustrated are top views 900, 906 and cross-sectional views 902, 904 of the next stage in the process flow. At this stage in the process flow, a fifth dielectric material 108 (shown as the “Dielectric 2” in the legend) can be formed in the bottom half of the gate openings, and a protective layer of a sixth dielectric material 126 (shown in the legend as “Dielectric 5”) can be formed in the upper half of the gate openings. To do so, the fifth dielectric material 108 can be deposited in the gate opening using any suitable material deposition technique. Then, the fifth dielectric material 108 can be directionally etched to be level above halfway through the stack of materials, as shown. Then, a (relatively thin) layer of the sixth dielectric material 126 can be deposited in the gate openings, using any suitable material deposition technique (e.g., ALD, CVD, PVD, PECVD, etc.). The sixth dielectric material can be deposited such that it does not entirely fill the upper half of the gate openings, and instead acts as a protective barrier for the stack of layers. The sixth dielectric material 126 can then be directionally etched to expose the fifth dielectric material 108 in the gate openings, as shown in the top views 900 and 906.

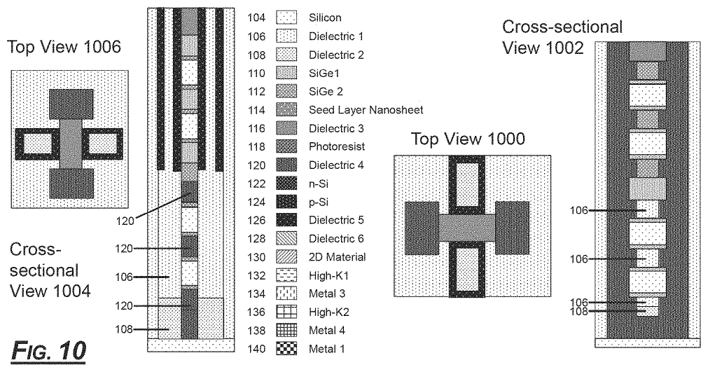

Referring to FIG. 10, illustrated are top views 1000, 1006 and cross-sectional views 1002, 1004 of the next stage in the process flow. At this stage in the process flow, the fifth dielectric material 108 can be selectively etched until the fifth dielectric material 108 is just below the bottom of the second layer of the first sacrificial material 110, as shown in the cross-sectional views 1002 and 1004. A gap between the second layer of the first sacrificial material 110 and the top of the fifth dielectric material 108 can form suitable space for active gate materials formed in later process steps. The removal technique used to partially remove the fifth dielectric material 108 can be de-selective to the sixth dielectric material 126, such that the sixth dielectric material 126 acts as a protective barrier for the layers in the upper half of the stack of layers. Then, the second dielectric material 112 in the bottom half of the stack of layers can be removed using a suitable etching technique. In some implementations, the etching technique used to remove the fifth dielectric material 108 may also be used to remove the second sacrificial material 112 (e.g., the etching technique is selective to the fifth dielectric material 108 and the second sacrificial material 112).

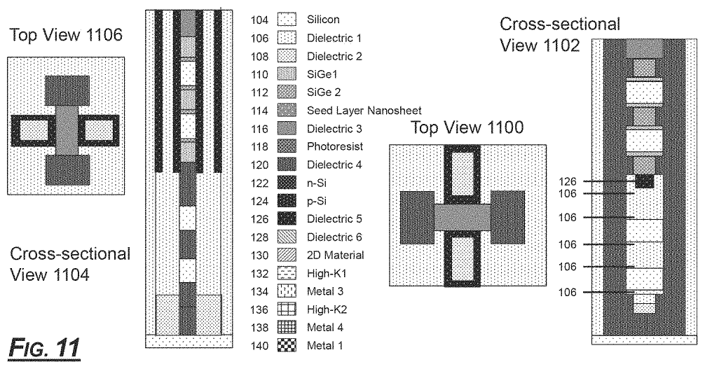

Referring to FIG. 11, illustrated are top views 1100, 1106 and cross-sectional views 1102, 1104 of the next stage in the process flow. At this stage in the process flow, the first sacrificial material 110 (e.g., surrounding the layers of the silicon 104) can be removed from the bottom half of the stack of layers, as shown in the cross-sectional views 1102 and 1104. Any suitable material removal technique can be used to remove the first sacrificial material 110, including but not limited to dry etching, wet etching, or plasma etching techniques, among others. The etching technique used to remove the first sacrificial material 110 can be selective to the first sacrificial material 110, such that the other layers in the stack of layers remain intact (e.g., those in the upper half being protected by the sixth dielectric material 126 and the second dielectric material 112). The space previously occupied by the first sacrificial material 110 that surrounds the silicon 104 can be used to form a channel material, and therefore the size of those layers of the first sacrificial material 110 may be selected in part based on the desired characteristics of the channel.

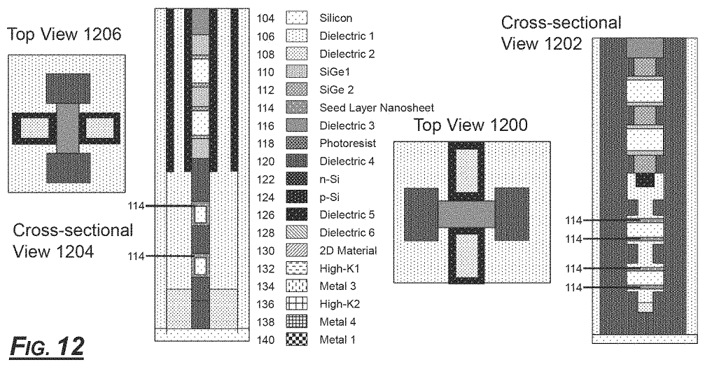

Referring to FIG. 12, illustrated are top views 1200, 1206 and cross-sectional views 1202, 1204 of the next stage in the process flow. At this stage in the process flow, a layer of a seed material 114 can be selectively deposited or selectively grown on the silicon 104. The seed material 114 can be, for example, SiO₂. However, it should be understood that other seed materials are also possible. Generally, any material that can be selectively formed on a substrate layer (e.g., the silicon 104) and that can behave as a seed layer for a 2D material, may be used as the seed material 114. The seed material 114 is formed in, but does not necessarily completely occupy, the space left when removing the layers of the first sacrificial material 110 previously in contact with the silicon 104. The type of the seed material 114 may be selected based on the desired type of 2D material to be formed. As shown in the cross-sectional view 1204, the seed material 114 may be formed to surround the silicon 104.

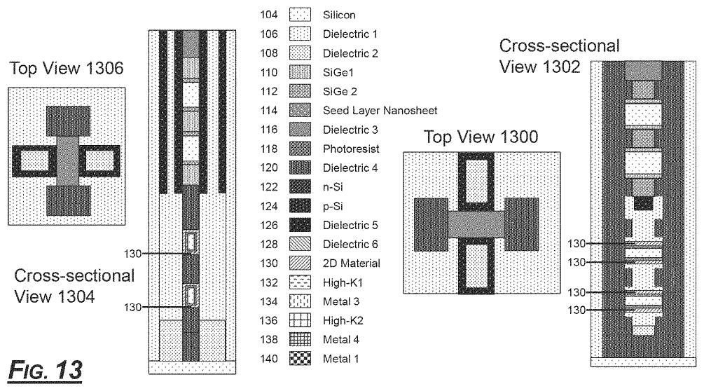

Referring to FIG. 13, illustrated are top views 1300, 1306 and cross-sectional views 1302, 1304 of the next stage in the process flow. At this stage in the process flow, the previously deposited layer of the seed material 114 may be recessed slightly to ensure that there is enough room to form the channel material. Any suitable selective etching technique may be used to recess the seed material 114. Then, a 2D material 130 (shown in the legend as “2D material”) can be formed on the seed material 114. The 2D material 130 can be formed to surround the layer of the seed material 114, as shown in the cross-sectional view 1304. The 2D material 130 can be any type of suitable material that may act as a semiconductive-behaving material, and may include WS₂, WSe₂, WTe₂, MoS₂, MoSe₂, MoTe₂, HfS₂, ZrS₂, TiS₂, GaSe, InSe, InGaZrO, or phosphorene, among others. The 2D material 130 can be selectively deposited on the seed material 114. Additionally or alternatively, the 2D material may include semiconductive behaving oxides (sometimes referred to herein as “conductive oxides”), which may have similar properties to semiconductor materials, to fabricate vertical 3D transistors. For example, certain materials, when combined with oxygen, may form new materials that exhibit semiconductor properties (e.g., can turn “off” with low off-state leakage current or can become highly conductive under certain circumstances). Some examples of N-type semiconductive behaving oxides include In₂O₃, SnO₂, InGaZnO, and ZnO. One example of a P-type conductive channel is SnO. The 2D material 130 can be deposited using any suitable material deposition technique, including ALD, CVD, PVD, PECVD, or epitaxial techniques, among others.

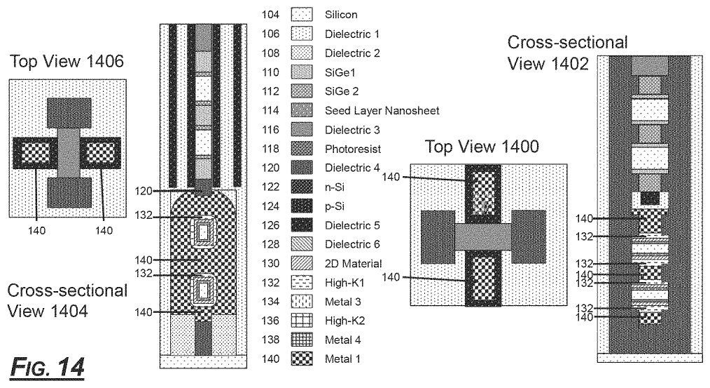

Referring to FIG. 14, illustrated are top views 1400, 1406 and cross-sectional views 1402, 1404 of the next stage in the process flow. At this stage in the process flow, a high-k dielectric material 132 (shown as “High-K1” in the legend) can be selectively deposited the 2D material 130 via the gate opening. The high-k dielectric material 132 acts as a gate dielectric material for the channel formed from the 2D material 130 and the semiconductive-behaving material 130, which is defined by the 2D material 130. The high-k dielectric material 132 can be any type of material with a relatively high dielectric constant, and may be deposited at a predetermined thickness to achieve a desired capacitance. In some implementations, the high-k dielectric material 132 can be selectively deposited or grown, such that the high-k dielectric material 132 is deposited only on the 2D material 130. The high-k dielectric material 132 may be deposited using any suitable material deposition technique, including but not limited to ALD, CVD, PVD, PECVD, or epitaxial techniques, among others. Then, after forming the high-k dielectric material 132, a gate metal 140 (shown as “Metal 1” in the legend) can be selectively formed on the high-k dielectric material 132. The gate metal 140 may be deposited using any suitable material deposition technique, including but not limited to ALD, CVD, PVD, PECVD, or epitaxial techniques, among others. In some implementations, the gate metal 140 may be grown on the high-k dielectric material 132, such that the high-k dielectric material 132 behaves as a seed material for the gate metal 140.

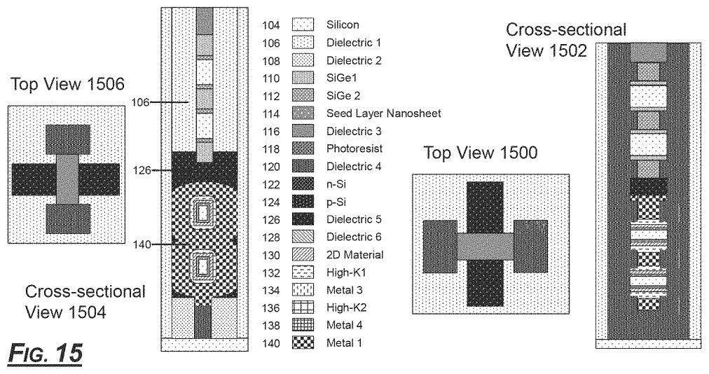

Referring to FIG. 15, illustrated are top views 1500, 1506 and cross-sectional views 1502, 1504 of the next stage in the process flow. At this stage in the process flow, the remaining gaps in the gate openings can be filled with the sixth dielectric material 126. Any suitable material deposition technique can be used to form the sixth dielectric material 126. The sixth dielectric material can both fill any remaining gaps above the gate metal 140, and the remaining space in the gate openings. A CMP process may then be performed. Then, the sixth dielectric material 126 can be selectively etched down to just above the bottom of the layer of the second sacrificial material 112 in the upper half of the device, as shown in the cross-sectional view 1504. This exposes the upper half of the stack of layers in the gate openings for further process steps, while isolating the bottom transistors formed in prior process steps.

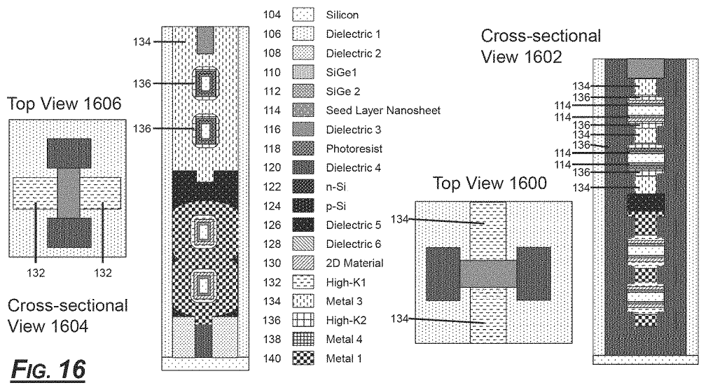

Referring to FIG. 16, illustrated are top views 1600, 1606 and cross-sectional views 1602, 1604 of the next stage in the process flow. At this stage in the process flow, similar processes to those described in connection with FIGS. 10-14 can be performed to form similar transistor structures. First, the second sacrificial material 112 and the first sacrificial material 110 can be removed, and a seed material 114 can be formed on the layers of the silicon 104. Then, the 2D material 130 can be formed on the seed material 114. In this example, a second high-k dielectric material 136 (shown as “High-K2” in the legend) can be formed on the 2D material 130, and a second gate metal 134 (shown as “Metal 3” in the legend) can be formed on the second high-k dielectric material 136. The choice of materials for these layers (e.g., the 2D material 130, the second high-k dielectric material 136, the second gate metal 134, etc.) is not limited those described herein. Indeed, any 2D material with any polarity (e.g., N-type, P-type, etc.) may be chosen. Similarly the types of the second high-k dielectric material 136 and the second gate metal 134 can be selected to have desired material characteristics, and/or to correspond to the chosen polarity of the transistor (e.g., P-type or N-type), or based on the chosen 2D material 130. As shown, the second gate metal 130 can fill the remaining space in the gate openings 130. After forming the second gate metal 130, a CMP process may be performed.

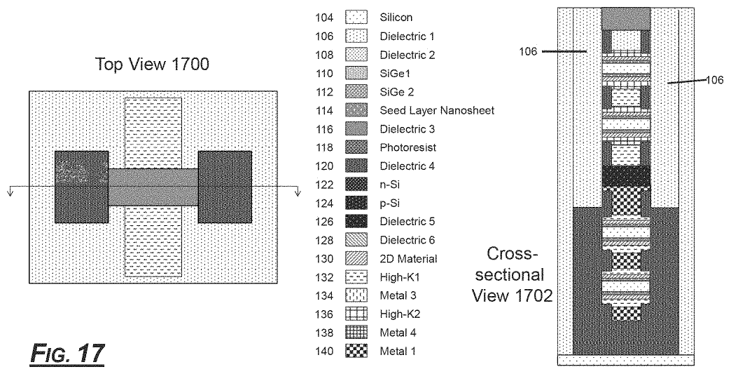

Referring to FIG. 17, illustrated is a top view 1700 and a cross-sectional view 1702 of the next stage in the process flow. At this stage in the process flow, the third dielectric material 120 can be selectively etched in the source/drain openings to a predetermined height. As shown in the cross-sectional view 1702, this may be just above the top of the high-k dielectric material 132 formed for the second transistor structure in the bottom half of the device. The etching process may be a directional etching process, such that the etching process does not remove the third dielectric material 120 that previously filled the recessed gates formed when etching the second sacrificial material 112. Any suitable etching technique may be used, including but not limited to dry etching, wet etching, or plasma etching techniques, among others.

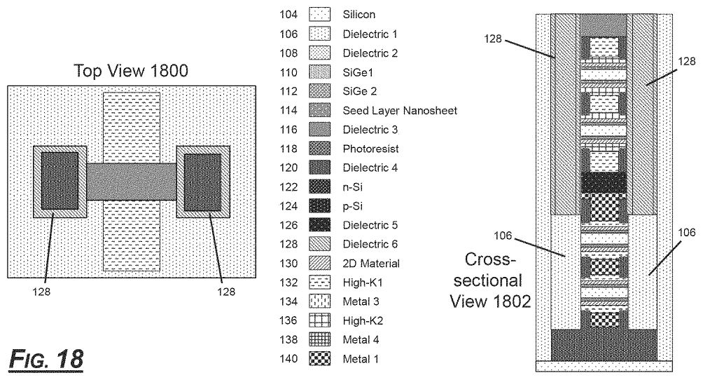

Referring to FIG. 18, illustrated is a top view 1800 and a cross-sectional view 1802 of the next stage in the process flow. At this stage in the process flow, a layer of the fourth dielectric material 128 can be deposited in the source/drain openings to protect the layers in the stack of layers from further process steps. The layer of the fourth dielectric material 128 can be a substantially thin layer of material, such that it does not entirely fill the source/drain openings, as shown in the cross-sectional view 1802. The fourth dielectric material 128 can then be directionally etched to expose the third dielectric material 120 in the source/drain openings. The third dielectric material 120 can then be selectively and directionally etched downward to expose both layers of the silicon 104 in the source/drain openings. An isotropic etch process may be performed to clean up the third dielectric material 120 from the silicon 104.

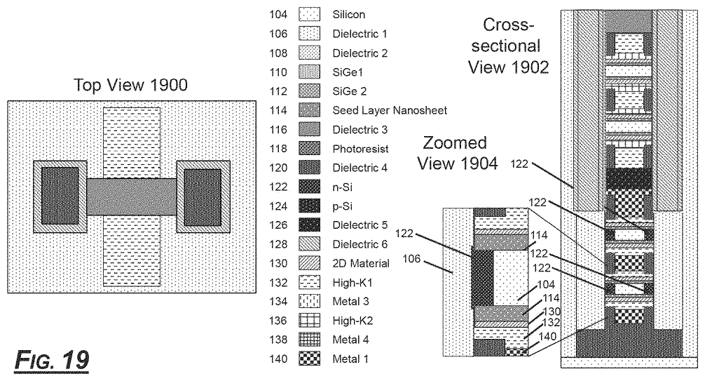

Referring to FIG. 19, illustrated is a top view 1900, a cross-sectional view 1902, and a zoomed view 1904 of the next stage in the process flow. At this stage in the process flow, the layers of the silicon 104 can be doped with a polarity opposite that of the desired polarity of source/drain contacts that will be formed in later process steps. For example, if the desired polarity of the source/drain contacts is an N-type polarity, a P-type doping process can be performed. Likewise, if the desired polarity of the source/drain contacts is a P-type polarity, an N-type doping process can be performed. Any suitable doping technique can be used, including, for example, plasma doping. Note that the layer of the third dielectric material 120 at the bottom of the device protects the base layer 104 from the doping process. This creates a first doped material 122 (shown as “n-Si” in the legend) on the silicon 104.

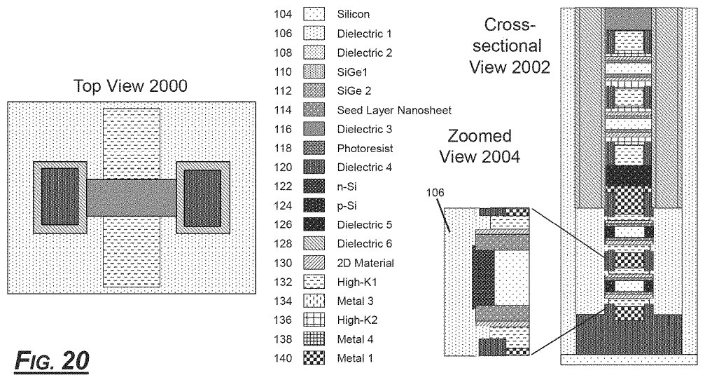

Referring to FIG. 20, illustrated is a top view 2000, a cross-sectional view 2002, and a zoomed view 2004 of the next stage in the process flow. At this stage in the process flow, a portion of the high-k dielectric material 132 can be recessed slightly, using any suitable selective etching technique, including but not limited to dry etching, wet etching, or plasma etching techniques, among others. Etching the high-k dielectric material 132 can provide more contact area between the source/drain material (formed in later process steps) and the 2D material 130 channel. The amount by which the high-k dielectric material 132 is recessed can be determined based on the desired contact area, which may be based on the desired characteristics of the transistor device.

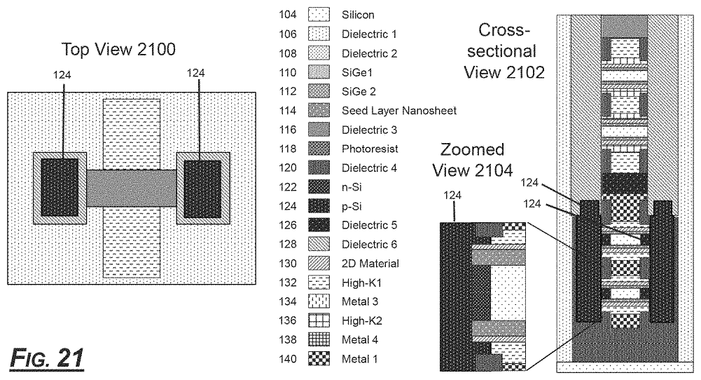

Referring to FIG. 21, illustrated is a top view 2100, a cross-sectional view 2102, and a zoomed view 2104 of the next stage in the process flow. At this stage in the process flow, second doped material 124 (shown as “p-Si” in the legend) can be grown on the first doped material 122. The second doped material 124 can form the source/drain contacts for the transistor devices, and can have an opposite polarity to the polarity of the first doped material 122. For example, if the first doped material 122 is doped to be an N-type material, the second doped material 124 can be formed as a P-type material, and vice versa. The second doped material 124 can be, for example, an epitaxially grown silicon material, which is formed to be doped with a desired polarity (e.g., N-type or P-type).

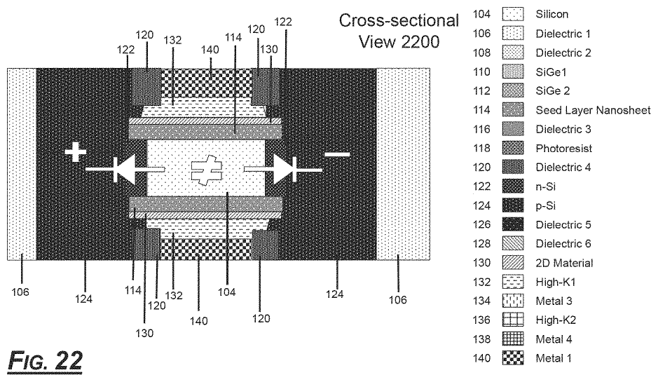

Referring to FIG. 22, illustrated is a cross-sectional view of one of the transistor structures formed using the prior process steps. As shown, two diodes are formed at the junction of the first doped material 122 (the doped region of the silicon 104 nano sheet) and the second doped material 124 (the doped source/drain region). With bias, one diode would be in forward bias, while the other would be operating in the cut-off region. This formation reduces the parallel leakage path/channel through the silicon 104 nano sheet, which is an improvement over conventional transistor devices.

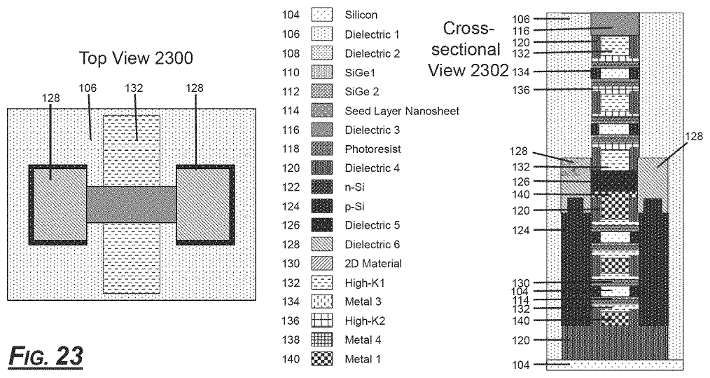

Referring to FIG. 23, illustrated is a top view 2300 and a cross-sectional view 2302 of the next stage in the process flow. At this stage in the process flow, the source/drain openings can be filled with the fourth dielectric material 128, to fill any openings above the second doped material 124 in the source/drain openings. A CMP process may then be performed. The fourth dielectric material 128 can then be directionally etched to expose the portions of the silicon 104 in the source/drain openings at the top of the device, similar to the processes described in connection with FIG. 18. The fourth dielectric material 128 provides isolation between the top and bottom transistors. The layers of the silicon 104 exposed in the source/drain openings can then be doped with a polarity opposite that of the desired polarity of source/drain contacts that will be formed in later process steps. For example, if the desired polarity of the source/drain contacts is an N-type polarity, a P-type doping process can be performed. Likewise, if the desired polarity of the source/drain contacts is a P-type polarity, an N-type doping process can be performed. Any suitable doping technique can be used, including, for example, plasma doping. Note that the layer of the third dielectric material 120 at the bottom of the device protects the base layer 104 from the doping process. This creates a second doped material 124 on the silicon 104 nano sheets.

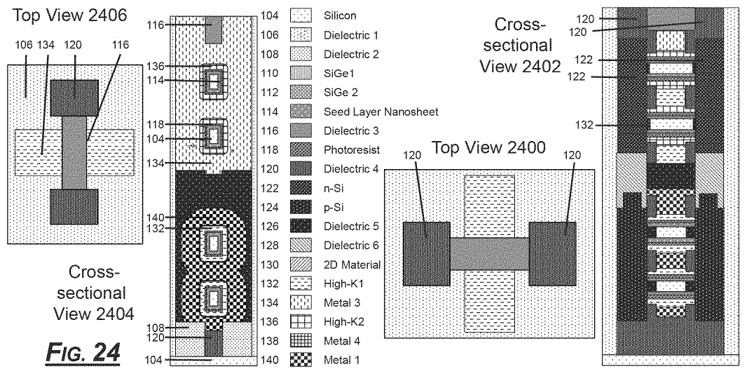

Referring to FIG. 24, illustrated are top views 2400, 2406 and cross-sectional views 2402, 2404 of the next stage in the process flow. At this stage in the process flow, the first doped material 122 can be grown on the second doped material 124 formed by doping the silicon 104 nano sheet. The first doped material 122 can form the source/drain contacts for the top transistor devices, and can have an opposite polarity to the polarity of the second doped material 124. For example, if the second doped material 124 is doped to be a P-type material, the first doped material 122 can be formed as an N-type material, and vice versa. The first doped material 122 can be, for example, an epitaxially grown silicon material, which is formed to be doped with a desired polarity (e.g., N-type or P-type). After growing the first doped material as the source/drain contacts for the top transistor devices, the first doped material 122 may be partially etched to a predetermined size.

Then, the third dielectric material 120 can be deposited using a suitable material deposition technique to fill any remaining space in the source/drain openings. A CMP process may then be performed to finish this process flow.

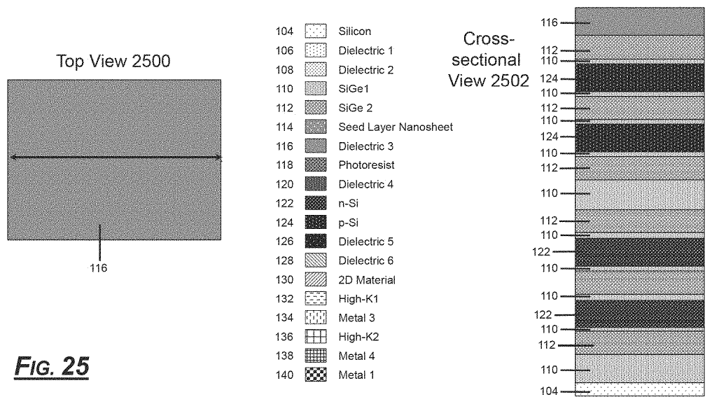

FIGS. 25-31 show various views of a second process flow to manufacture semiconductor devices with 3D single crystal silicon nano sheets integrated with 2D materials. Each of the FIGS. 25-31 generally refer to one or more process steps in a process flow, each of which are described in detail in connection with a respective Figure. For the purposes of simplicity and ease of visualization, some reference numbers may be omitted from some Figures. Referring to FIG. 25, illustrated is a top view 2500 and a cross-sectional view 2502 of a base structure. As shown, the base structure formed in FIG. 25 can be substantially similar to the base structure described in connection with FIG. 1. However, rather than utilizing nano sheets of the silicon 104 material, instead the a first and second layer of the first doped material 122 are provided for the transistors at bottom of the device, and a first and second layer of the second doped material 124 are provided for the transistors at the top of the device.

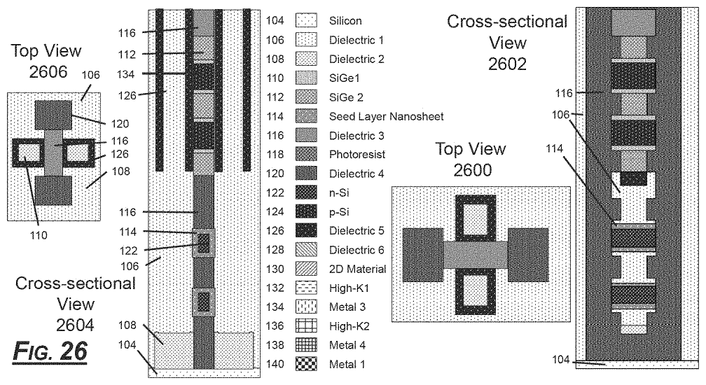

Referring to FIG. 26, illustrated are top views 2600, 2606 and cross-sectional views 2602, 2604 of the next stage in the process flow. At this stage in the process flow, steps similar to those described in connection with FIGS. 2-12 can be performed on the base structure formed in FIG. 25. One difference is that because the first doped material 122 is already doped, in contrast to the silicon 104, the seed material 114 can extend further into the doped region than in the silicon 104 case.

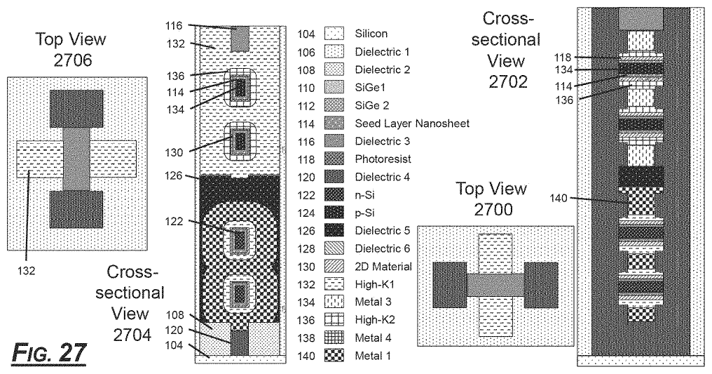

Referring to FIG. 27, illustrated are top views 2700, 2706, and cross-sectional views 2702, 2704 of the next stage in the process flow. At this stage in the process flow, steps similar to those described in connection with FIGS. 13-16 can be performed after performing the steps described in connection with FIG. 26. The difference between the techniques in FIGS. 13-16, and FIG. 26 is that the nano sheet layers of the first doped material 122 and the second doped material 124 are used, rather than nano sheet layers of the silicon 104 material.

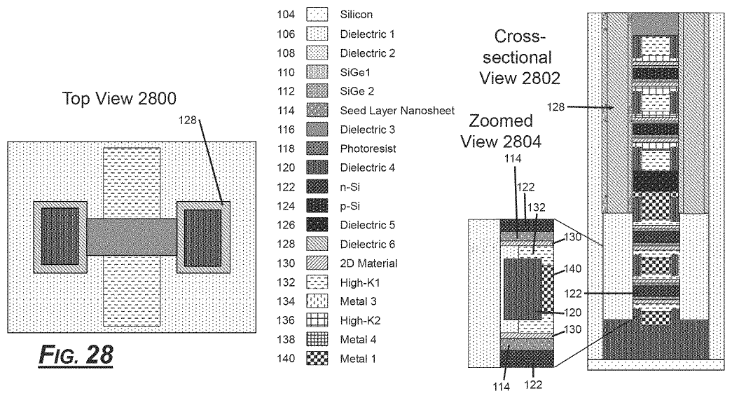

Referring to FIG. 28, illustrated is a top view 2800, a cross-sectional view 2802, and a zoomed view 2804 of the next stage in the process flow. At this stage in the process flow, process steps similar to those described in connection with FIGS. 17-20 can be performed, except that doping of the silicon 104 is not needed, because the nano sheets of the first doped material 122 are already doped with a first polarity. As shown, a layer of the fourth dielectric material 128 has been formed in accordance with the process steps described in FIGS. 17-20, to protect the upper layers of the base structure while performing process steps to form the lower transistors.

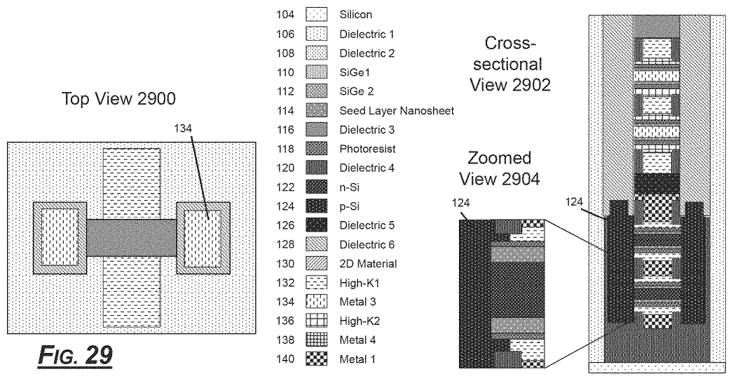

Referring to FIG. 29, illustrated is a top view 2900, a cross-sectional view 2902, and a zoomed view 2904 of the next stage in the process flow. At this stage in the process flow, process steps similar to those described in connection with FIG. 21 may be performed to form the second doped material 124 as the source/drain contacts for the bottom two transistor structures. The second doped material 124 can have a polarity that is opposite to the polarity of the first doped material 122 nano sheets, on which the seed material 114 was deposited.

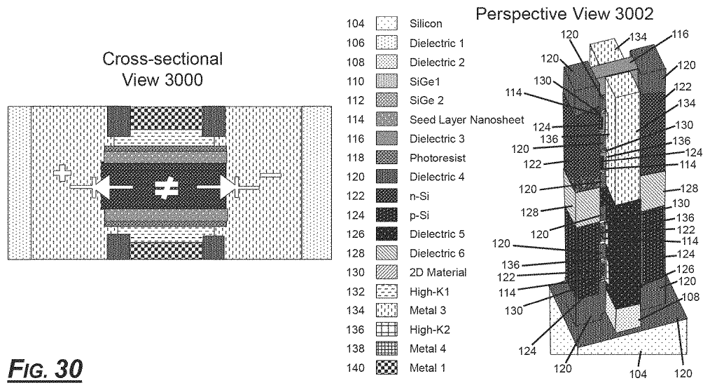

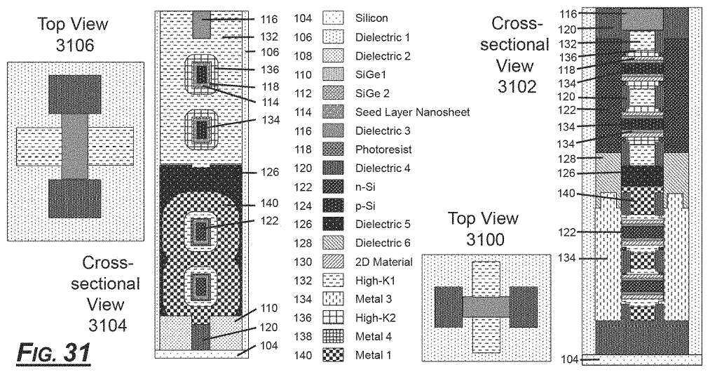

Referring to FIG. 30, illustrated is a cross-sectional view 3000 and a perspective view 3002 of the next stage in the process flow. At this stage in the process flow, steps similar to those performed in connection with FIGS. 22-24 can be performed to finalize the device. However, rather than doping the silicon 104 to create portions of the second doped material 124, nano sheets of the second doped material 124 were used in place of the nano sheets of the silicon 104. As shown in the cross-sectional view 3000, two diodes are formed at the junction of the nano sheet of the first doped material 122 and the source/drain formed from the second doped material 124. With bias, one diode would be in forward bias while the other would be in reverse bias. Therefore, one diode would be cut-off. This reduces the parallel leakage path/channel through the nano sheet, which is an improvement over conventional semiconductor devices. FIG. 31 shows top views 3100, 3106 and cross-sectional views 3102, 3104 of the device formed using such process steps.

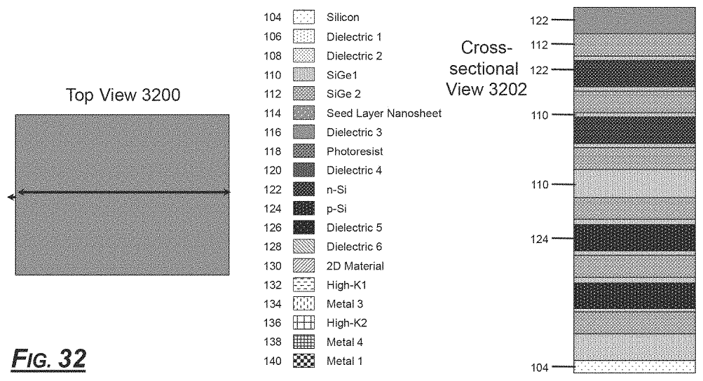

FIGS. 32-36 show various views of a third process flow to manufacture semiconductor devices with 3D single crystal silicon nano sheets integrated with 2D materials. Each of the FIGS. 32-36 generally refer to one or more process steps in a process flow, each of which are described in detail in connection with a respective Figure. For the purposes of simplicity and ease of visualization, some reference numbers may be omitted from some Figures. Referring to FIG. 32, illustrated is a top view 3200 and a cross-sectional view 3202 of a base structure. As shown, the base structure formed in FIG. 32 can be substantially similar to the base structure described in connection with FIGS. 1 and 25. However, rather than utilizing nano sheets of the silicon 104 material as in FIG. 1, and instead of the configuration in FIG. 25, a first and second layer of the second doped material 124 are provided for the transistors at bottom of the device, and a first and second layer of the first doped material 122 are provided for the transistors at the top of the device. This is the reverse of what is shown in FIG. 25, where the first doped material 122 was used for the bottom two transistors, and the second doped material 124 was used for the top two transistors.

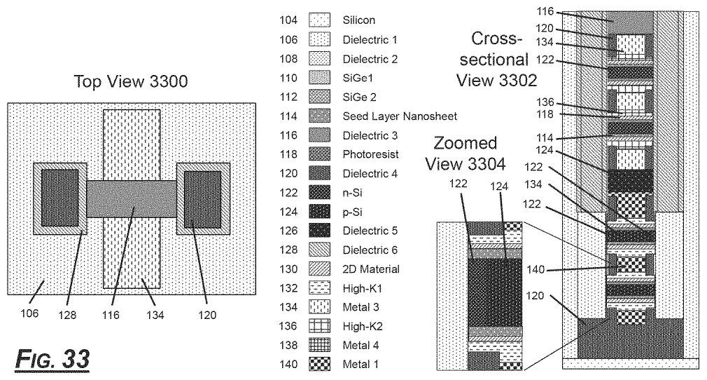

Referring to FIG. 33, illustrated is a top view 3300, a cross-sectional view 3302, and a zoomed view 3304 of the next stage in the process flow. At this stage in the process flow, process steps similar to those described in connection with FIGS. 1-19 can be performed on the base structure described in connection with FIG. 31. However, rather than doping the nano sheet of the silicon 104 material, instead the nano sheets layers of the second doped material 124 can be doped with the opposite polarity (e.g., N-type of the second doped material is P-type, P-type if the second doped material 124 is N-type). This creates regions of the first doped material 122 on the layers of the second doped material 124.

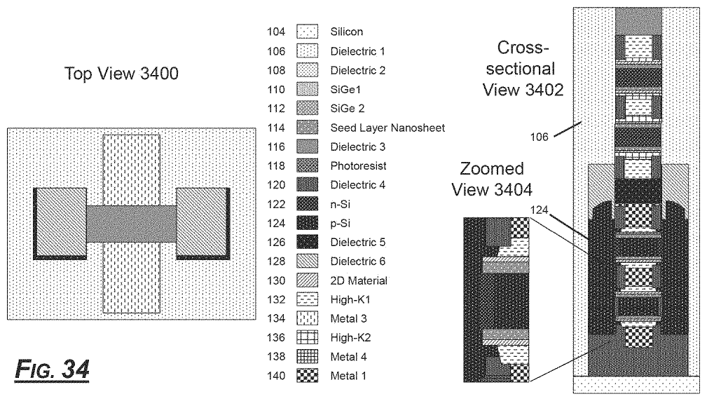

Referring to FIG. 34, illustrated is a top view 3400, a cross-sectional view 3402, and a zoomed view 3404 of the next stage in the process flow. At this stage in the process low, process steps similar to those described in connection with FIGS. 20-21 can be performed to form source/drain contacts using the second doped material 124 in the source/drain openings of the base structure. As shown, the polarity of the second doped material 124 and the polarity of the nano sheet (also the second doped material 124) are the same, but are separated by a region of the first doped material 122 (formed by doping the nano sheet of the second doped material 124 with the opposite polarity).

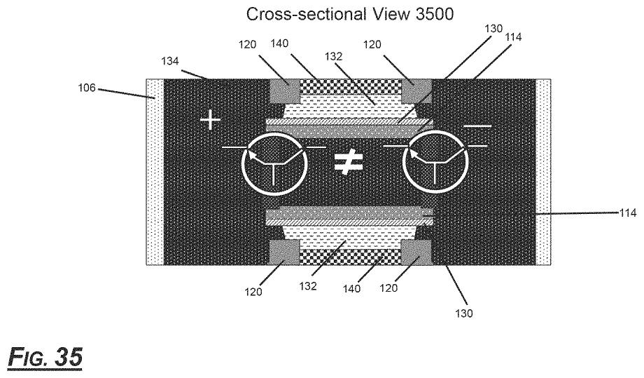

Referring to FIG. 35, illustrated is a cross-sectional view 3500 of the device formed in the previous process steps. As shown, the two p-n-p junctions are formed at the junction of the nano sheet of the second doped material 124, the plasma doped region of the first doped material 122, and the source/drain contact formed from the second doped material 124. This creates bipolar junction transistor (BJT) enhancement at the source/drain and channel regions. With bias, there would be no path between the source and drain through the silicon, and therefore only the 2D material 130 would serve as the channel.

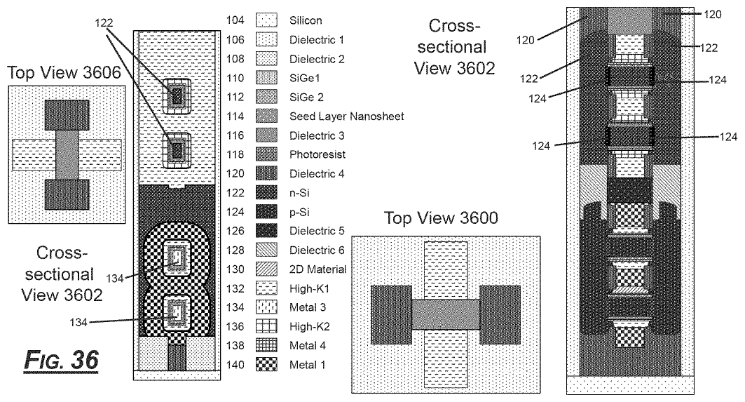

Referring to FIG. 36, illustrated are top views 3600, 3606 and cross-sectional views 3602, 3604 of the next stage in the process flow. At this stage in the process flow, process steps similar to those described in connection with FIGS. 23-24 can be performed to form source/drain contacts using the first doped material 122 in the source/drain openings of the base structure. As shown, the polarity of the first doped material 122 and the polarity of the nano sheet (also the first doped material 122) are the same, but are separated by a region of the second doped material 124 (formed by doping the nano sheet of the second doped material 124 with the opposite polarity). This creates the BJT enhancement in the device, as described above.

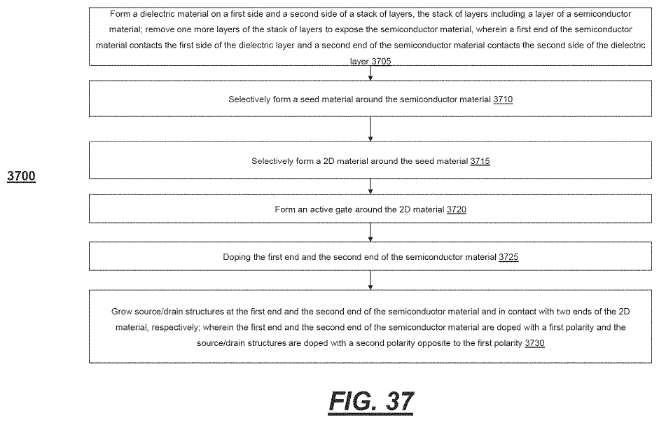

Referring to FIG. 37, illustrated is a flow diagram of a method 3700 for fabricating semiconductor devices. The method 3700 may include steps 3705-3725. However, other embodiments may include additional or alternative steps, or may omit one or more steps altogether.

Referring to step 3705, the method 3700 includes forming a bridge-like structure of a semiconductor material (e.g., silicon 104). The method may include forming a dielectric material on a first side and a second side of a stack of layers (as shown in FIG. 1), the stack of layers including a layer of the semiconductor material. One or more layers (e.g., sacrificial material) of the stack of layers may be removed (e.g., as described with respect to FIG. 11) to expose the semiconductor material. As a result, a first end of the semiconductor material contacts the first side of the dielectric layer and a second end of the semiconductor material contacts the second side of the dielectric layer. In some implementations, a substrate material may be a doped material (e.g., the first doped material 122 or the second doped material 124), as described in connection with FIG. 25 or 32. The substrate material may be formed between layers of a sacrificial material (e.g., the first sacrificial material 110 or the second sacrificial material 112).

Referring to step 3710, the method 3700 includes selectively forming a seed material (e.g., the seed material 114) around the semiconductor material. To form the seed material, process steps described in connection with FIGS. 2-12 may be performed. If the substrate material is a doped substrate material, the process steps described in connection with FIGS. 25-26 may be performed.

Referring to step 3715, the method 3700 includes selectively forming a 2D material (e.g., the 2D material 130) around the seed material. To do so, process steps similar to those described in connection with FIG. 13 may be performed. In some implementations, portions of a sacrificial material may be removed and replaced with the seed material or the 2D material.

Referring to step 3720, the method 3700 includes forming an active gate around the 2D material. An “active gate” may be any materials that form a gate for a transistor structure (e.g., the high-k dielectric 132, the second high-k dielectric 136, the gate metal 140, the second gate metal 134, etc.). To form the active gate, process steps similar to those described in connection with FIG. 13 or 16 may be performed. The active gate materials may replace one or more sacrificial layers in the base structure.

Referring to step 3725, the method 3700 includes doping the first end and the second end of the semiconductor material, as described with respect to FIG. 19. At this stage in the process flow, the semiconductor material can be doped with a polarity opposite that of the desired polarity of source/drain structures that will be formed in later process steps. For example, if the desired polarity of the source/drain structures is an N-type polarity, a P-type doping process can be performed. Likewise, if the desired polarity of the source/drain structures is a P-type polarity, an N-type doping process can be performed.

Referring to step 3730, the method 3700 includes growing source/drain structures at the semiconductor material and in contact with two ends of the 2D material, respectively; such that the semiconductor has at least end portions doped with a first polarity and the source/drain structures are each doped with a second polarity opposite to the first polarity. Growing the source/drain contact may be performed via one or more source/drain openings in the base structure. To form the source/drain contacts, the process steps described in connection with FIGS. 20-24 may be performed.

Having now described some illustrative implementations and implementations, it is apparent that the foregoing is illustrative and not limiting, having been presented by way of example. In particular, although many of the examples presented herein involve specific combinations of method acts or system elements, those acts and those elements may be combined in other ways to accomplish the same objectives. Acts, elements, and features discussed only in connection with one implementation are not intended to be excluded from a similar role in other implementations or implementations.

The phraseology and terminology used herein is for the purpose of description and should not be regarded as limiting. The use of “including,” “comprising,” “having,” “containing,” “involving,” “characterized by,” “characterized in that,” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned, or un-patterned, but rather, is contemplated to include any such layer or base structure, and any combination of layers and/or base structures. The description may reference particular types of substrates, but this is for illustrative purposes only.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act, or element may include implementations where the act or element is based at least in part on any information, act, or element.

Any implementation disclosed herein may be combined with any other implementation, and references to “an implementation,” “some implementations,” “an alternate implementation,” “various implementation,” “one implementation,” or the like are not necessarily mutually exclusive and are intended to indicate that a particular feature, structure, or characteristic described in connection with the implementation may be included in at least one implementation. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms.

Where technical features in the drawings, detailed description, or any claim are followed by reference signs, the reference signs have been included for the sole purpose of increasing the intelligibility of the drawings, detailed description, and claims. Accordingly, neither the reference signs nor their absence have any limiting effect on the scope of any claim elements.

The preceding description of the disclosed embodiments is provided to enable any person skilled in the art to make or use the embodiments described herein and variations thereof. Various modifications to these embodiments will be readily apparent to those skilled in the art, and the principles defined herein may be applied to other embodiments without departing from the spirit or scope of the subject matter disclosed herein. Thus, the present disclosure is not intended to be limited to the embodiments shown herein but is to be accorded the widest scope consistent with the following claims and the principles and novel features disclosed herein.

While various aspects and embodiments have been disclosed, other aspects and embodiments are contemplated. The various aspects and embodiments disclosed are for purposes of illustration and are not intended to be limiting, with the true scope and spirit being indicated by the following claims.

What is claimed is:

1. A method, comprising:
forming a dielectric material on a first side and a second side of a stack of layers, the stack of layers including a layer of a semiconductor material;
removing one more layers of the stack of layers to expose the semiconductor material, wherein a first end of the semiconductor material contacts the first side of the dielectric layer and a second end of the semiconductor material contacts the second side of the dielectric layer;
selectively forming a seed material around the semiconductor material;
selectively forming a two-dimensional (2D) material around the seed material;
forming an active gate round the 2D material;
doping the first end and the second end of the semiconductor material; and
growing source/drain structures at the first end and the second end of the semiconductor material and in contact with two ends of the 2D material, respectively,
wherein the first end and the second end of the semiconductor material are doped with a first polarity and the source/drain structures are doped with a second polarity opposite to the first polarity.

2. The method of claim 1, wherein the semiconductor material is silicon, and wherein doping the first end and the second end of the semiconductor material comprises performing a p-type doping process on the silicon.

3. The method of claim 1, wherein the semiconductor material is silicon, and wherein doping the first end and the second end of the semiconductor material comprises performing an n-type doping process on the silicon.

4. The method of claim 1, wherein the stack of layers includes one or more layers of a sacrificial material on the semiconductor material.

5. The method of claim 4, wherein forming the seed material and the 2D material comprises replacing the one or more layers of the sacrificial material with the seed material and the 2D material.

6. The method of claim 1, wherein forming the active gate comprises:
forming a high-k dielectric material on the 2D material; and
forming a gate metal on the high-k dielectric material.

7. The method of claim 2, wherein growing the source/drain structures is performed via a one or more openings in the stack of layers.

8. A device, comprising:
a semiconductor material and having a first end and a second end doped with a first polarity;
a seed material around the semiconductor material;
a two-dimensional (2D) material around the seed material;
an active gate around the 2D material; and
a source/drain structure in contact with the first end and the second end of the semiconductor material and in contact with the 2D material, wherein the source/drain structure is doped with a second polarity opposite to the first polarity.

9. The device of claim 8, wherein a remaining portion of the bridge is doped with the second polarity such that a bipolar junction transistor (BJT) is formed by the source/drain structure, the first end of the semiconductor material, and a portion of the semiconductor material.

10. The device of claim 8, wherein a diode is formed by the source/drain structure and the first end of the semiconductor material.

11. The device of claim 8, wherein the active gate further comprises a high-k dielectric around the 2D material, and the source/drain structure is electrically isolated from a gate metal of the active gate with the high-k dielectric.

12. The device of claim 8, wherein the semiconductor material includes silicon.

13. The device of claim 8, wherein the first polarity is n-type, and the second polarity is p-type.

14. A transistor structure comprising:
a two-dimensional (2D) channel material partially around a semiconductor material that is at least partially doped with a first polarity;
a high-k dielectric partially around the 2D channel material;
a gate metal partially around the high k-dielectric;
a source metal doped with a second polarity that is opposite to the first polarity, the source metal in contact with the 2D material; and
a drain metal doped with the second polarity and in contact with the 2D material.

15. The transistor structure of claim 14, further comprising a seed material around the semiconductor material, wherein the 2D channel material is in contact with the seed material.

16. The transistor structure of claim 14, wherein the source metal and the drain metal are coupled to a portion of the semiconductor material that is doped with the first polarity.

17. The transistor structure of claim 14, wherein the source metal and the drain metal are coupled to the 2D material and the high-k dielectric material.

18. The transistor structure of claim 14, wherein a central portion of the semiconductor material is doped with the second polarity, and end portions of the semiconductor material are doped with the first polarity.

19. The transistor structure of claim 14, wherein the semiconductor material includes silicon.

20. The transistor structure of claim 14, wherein the first polarity is n-type, and the second polarity is p-type.
